(19) United States
(12) Patent Application Publication
(10) Pub. No.: US 2016/0172054 A1
(43) Pub. Date: Jun. 16, 2016

(54) SHIFT REGISTER UNIT, ITS DRIVING METHOD, SHIFT REGISTER AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Xianjie SHAO, Beijing (CN); Xiaohe LI, Beijing (CN)

(73) Assignees: HEFEI BOE OPTOELECTRONICS TECHNOLOGY CO., LTD., Hefei (CN); BOE TECHNOLOGY GROUP CO., LTD., Beijing (CN)

(21) Appl. No.: 14/796,499

(22) Filed: Jul. 10, 2015

(30) Foreign Application Priority Data
Dec. 15, 2014 (CN) 201410776422.8

(51) Int. Cl. G11C 19/18; G09G 3/36

(52) U.S. Cl. CPC G11C 19/184; G09G 3/3648; G09G 2310/0286; G09G 2310/0283

(57) ABSTRACT

A shift register unit includes a gate driving signal output end, an input end, a reset end, a clock signal end, a pull-up transistor, a pull-down transistor, a pull-down node control module and a pull-up node control module. The pull-down node control module is configured to control a pull-down node to be at a low potential at an input stage, control the pull-down transistor to be in an off state at an output stage, pull up the potential of the pull-down transistor at a reset stage, and control the pull-down transistor to be in the on state at a maintenance stage, so as to enable the gate driving signal output end to output a low level. The pull-up node control module is configured to pull up a pull-up node to be at a high potential at the input stage, control the pull-up transistor to be in an on state at the output stage so as to enable the gate driving signal output end to output a clock signal, pull down the pull-up node to be at a low level at the reset stage, and control the pull-up transistor to be in an off state at the maintenance stage.

### CROSS-REFERENCE TO RELATED APPLICATION

The present application claims a priority of the Chinese patent application No. 201410776422.8 filed on Dec. 15, 2014, which is incorporated herein by reference in its entirety.

### TECHNICAL FIELD

The present disclosure relates to the field of display technology, in particular to a shift register unit, its driving method, a shift register, and a display device.

### BACKGROUND

A thin film transistor liquid crystal display (TFT-LCD) driver includes a gate driver and a data driver, and a shift register unit is usually used in the gate driver of a liquid crystal display panel. Each gate line is connected to one level of shift register unit, and an inputted clock signal is converted by the shift register unit and then applied by the gate driver to the gate line of the liquid crystal display panel. A shift register consists of a plurality of levels of shift register units, and a gate driving signal is outputted by the shift register, so as to scan pixels in each row on the liquid crystal panel progressively.

However, it is impossible for an existing shift register unit and an existing shift register to achieve bi-direction scanning with a simple circuit structure, so a large number of transistors are required and the resultant power consumption is high.

### SUMMARY

A main object of the present disclosure is to provide a shift register unit, its driving method, a shift register, and a display device, so as to achieve bi-direction scanning with a simple circuit structure and reduce the number of transistors desired to be used, thereby to reduce the power consumption.

In one aspect, the present disclosure provides in one embodiment a shift register unit, including a gate driving signal output end, an input end, a reset end, a clock signal end, a pull-up transistor, a pull-down transistor, a pull-down node control module and a pull-up node control module.

A gate electrode of the pull-up transistor is connected to a pull-up node, a first electrode thereof is connected to the clock signal end, and a second electrode thereof is connected to the gate driving signal output end.

A gate electrode of the pull-down transistor is connected to a pull-down node, a first electrode thereof is connected to the gate driving signal output end, and a second electrode thereof is configured to receive a first low level.

The pull-down node control module is configured to receive the first low level and a first high level, connected to the pull-up node and the pull-down node, and configured to control the pull-down node to be at a low potential at an input stage of each display period and control the pull-down node to be maintained at a low potential at an output stage of each display period so as to control the pull-down transistor to be in an off state, and to control the pull-down node to be pulled up to a high level at a reset stage of each display period and control the potential of the pull-down node to be pulled up continuously at a maintenance stage of each display period so as to control the pull-down transistor to be in an on state, thereby to enable the gate driving signal output end to output a low level.

The pull-up node control module is configured to receive the first low level, a second low level and a second high level, connected to the pull-up node, the pull-down node, the input end and the reset end, and configured to control the pull-up node to be pulled up to a high potential at the input stage of each display period and control the potential of the pull-up node to be bootstrapped at the output stage of each display period so as to control the pull-up transistor to be maintained in an on state and enable the gate driving signal output end to output a clock signal from the clock signal end, and to control the pull-up node to be pulled down to a low level at the reset stage of each display period and control the pull-up node to be maintained at a low level at the maintenance stage of each display period so as to control the pull-up transistor to be in an off state.

During the implementation, the pull-down node control module includes: a first pull-down node control transistor, a gate electrode of which is configured to receive the first high level, a first electrode of which is configured to receive the first high level, and a second electrode of which is connected to the pull-down node; and a second pull-down node control transistor, a gate electrode of which is connected to the pull-up node, a first electrode of which is connected to the pull-down node, and a second electrode of which is configured to receive the first low level.

During the implementation, the pull-up node control module includes a first transistor, a second transistor, a pull-up node control transistor and a storage capacitor. A gate electrode of the pull-up node control transistor is connected to the pull-down node, a first electrode thereof is connected to the pull-up node, and a second electrode thereof is configured to receive the first low level. The storage capacitor is connected between the pull-up node and the gate driving signal output end. During forward scanning, a gate electrode of the first transistor is connected to the reset end, a first electrode is configured to receive the second low level, and a second electrode thereof is connected to the pull-up node; and a gate electrode of the second transistor is connected to the input end, a first electrode thereof is connected to the pull-up node, and a second electrode thereof is configured to receive the second high level. During backward scanning, the gate electrode of the first transistor is connected to the input end, the first electrode thereof is configured to receive the second high level, and the second electrode thereof is connected to the pull-up node; and the gate electrode of the second transistor is connected to the reset end, the first electrode thereof is connected to the pull-up node, and the second electrode thereof is configured to receive the second low level.

During the implementation, the pull-up transistor, the pull-down transistor, the pull-up node control transistor, the first pull-down node control transistor and the second pull-down node control transistor are all n-type transistors.

In another aspect, the present disclosure provides in one embodiment a method for driving the above-mentioned shift register unit, including, during forward scanning and backward scanning within each display period, steps of:

at an input stage, enabling an input end to receive a high level, enabling a reset end to receive a low level, enabling a clock signal end to receive a low level, controlling by a pull-up node control module a pull-up node to be pulled up to a high potential so as to control a pull-up transistor to be in an on state, and controlling by a pull-down node control module a pull-down node to be pulled down to a low level so as to control a pull-down transistor to be in an off state, thereby enabling a gate driving signal output end to output a low level;

at an output stage, enabling the input end to receive a low level, enabling the reset end to receive a low level, enabling the clock signal end to receive a high level, controlling by the pull-up node control module the potential of the pull-up node to be bootstrapped so as to control the pull-up transistor to be maintained in the on state, and controlling by the pull-down node control module the pull-down node to be maintained at a low level so as to control the pull-down transistor to be maintained in the off state, thereby enabling the gate driving signal output end to output a high level;

at a reset stage, enabling the input end to input a low level, enabling the reset end to receive a high level, controlling by the pull-up node control module the potential of the pull-up node to be pulled down so as to control the pull-up transistor to be in an off state, and controlling by the pull-down node control module the pull-down node to be pulled up to a high level so as to control the pull-down transistor to be in an on state, thereby enabling the gate driving signal output end to output a low level; and

at a maintenance stage, controlling by the pull-up node control module the pull-up node to be maintained at a low level so as to control the pull-up transistor to be in the off state, and controlling by the pull-down node control module the potential of the pull-down node to be pulled up continuously so as to control the pull-down transistor to be in the on state, thereby enabling the gate driving signal output end to output a low level continuously.

In yet another aspect, the present disclosure provides in one embodiment a shift register, including multiple levels of the above-mentioned shift register units arranged on an array substrate. An input end of a first-level shift register unit is configured to receive a startup signal. Apart from the first-level shift register unit, an input end of a current-level shift register unit is connected to a gate driving signal output end of a previous-level shift register unit; and apart from a last-level shift register unit, a reset end of a current-level shift register unit is connected to a gate driving signal output end of a next-level shift register unit. A reset end of the last-level shift register unit is configured to receive a reset signal. Clock signals received by clock signal ends of two adjacent levels of the shift register units are of phases reverse to each other.

In still yet another aspect, the present disclosure provides in one embodiment a display device including the above-mentioned shift register unit.

As compared with the related art, it is able for the shift register unit in the present disclosure to achieve the bi-direction scanning with a simple circuit structure, thereby to reduce the number of the transistors desired to be used as well as the resultant power consumption.

### BRIEF DESCRIPTION OF THE DRAWINGS

FIG. 1 is a schematic view showing a shift register unit according to one embodiment of the present disclosure;

FIG. 2 is a schematic view showing a shift register according to one embodiment of the present disclosure;

FIG. 3 is a circuit diagram of the shift register unit according to one embodiment of the present disclosure;

FIG. 4 is a sequence diagram of the shift register unit in FIG. 3;

FIG. 5 is another circuit diagram of the shift register unit according to one embodiment of the present disclosure; and

FIG. 6 is a sequence diagram of the shift register unit in FIG. 5.

### DETAILED DESCRIPTION

The present disclosure will be described hereinafter in a clear and complete manner in conjunction with the drawings and embodiments. Obviously, the following embodiments are merely a part of, rather than all of, the embodiments of the present disclosure, and based on these embodiments, a person skilled in the art may, without any creative effort, obtain the other embodiments, which also fall within the scope of the present disclosure.

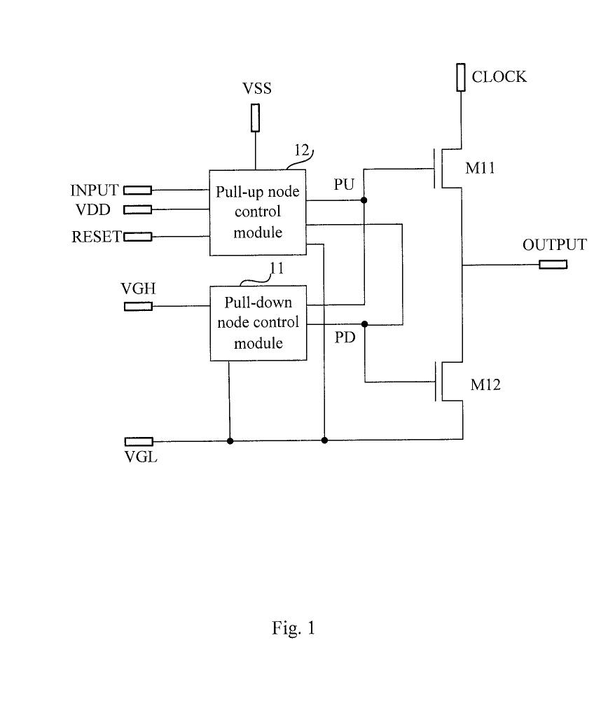

As shown in FIG. 1, the present disclosure provides in one embodiment a shift register unit, which includes a gate driving signal output end OUTPUT, an input end INPUT, a reset end RESET, a clock signal end CLOCK, a pull-up transistor M11, a pull-down transistor M12, a pull-down node control module 11 and a pull-up node control module 12.

A gate electrode of the pull-up transistor M11 is connected to a pull-up node PU, a first electrode thereof is connected to the clock signal end CLOCK, and a second electrode thereof is connected to the gate driving signal output end OUTPUT.

A gate electrode of the pull-down transistor M12 is connected to a pull-down node PD, a first electrode thereof is connected to the gate driving signal output end OUTPUT, and a second electrode thereof is configured to receive a first low level VGL.

The pull-down node control module 11 is configured to receive the first low level VGL and a first high level VGH, connected to the pull-up node PU and the pull-down node PD, and configured to control the pull-down node PD to be at a low potential at an input stage of each display period and control the pull-down node PD to be maintained at a low potential at an output stage of each display period so as to control the pull-down transistor M12 to be in an off state, and to control the pull-down node PD to be pulled up to a high level at a reset stage of each display period and control the potential of the pull-down node PD to be pulled up continuously at a maintenance stage of each display period so as to control the pull-down transistor M12 to be in an on state, thereby to enable the gate driving signal output end OUTPUT to output a low level.

The pull-up node control module 12 is configured to receive the first low level VGL, a second low level VSS and a second high level VDD, connected to the pull-up node PU, the pull-down node PD, the input end INPUT and the reset end RESET, and configured to control the pull-up node PU to be pulled up to a high potential at the input stage of each display period and control the potential of the pull-up node PU to be bootstrapped at the output stage of each display period so as to control the pull-up transistor M11 to be maintained in an on state and enable the gate driving signal output end OUTPUT to output a clock signal from the clock signal end CLOCK, and to control the pull-up node PU to be pulled down to a low level at the reset stage of each display period and control the pull-up node PU to be maintained at a low level at the maintenance stage of each display period so as to control the pull-up transistor M11 to be in an off state.

In this embodiment, the pull-up transistor M11 and the pull-down transistor M12 of the shift register unit are both n-type transistors.

According to the shifter register unit in the embodiment of the present disclosure, it is able to achieve bi-direction scanning with a simple circuit structure, thereby to reduce the number of the transistors desired to be used as well as the resultant power consumption.

The transistors adopted in all embodiments of the present disclosure may be thin film transistors (TFTs), field effect transistors (FETs) or any other elements having the same characteristics. In the embodiments of the present disclosure, in order to differentiate two electrodes of the transistor other than the gate electrode, the first electrode may be a source electrode or a drain electrode, and the second electrode may be a drain electrode or a source electrode. In addition, depending on its characteristics, the transistor may be an n-type transistor or a p-type transistor. In a driver circuit provided in the embodiments of the present disclosure, all the transistors are n-type transistors. Of course, p-type transistors may also be adopted, which are not particularly defined herein.

To be specific, the pull-down node control module includes: a first pull-down node control transistor, a gate electrode of which is configured to receive the first high level, a first electrode of which is configured to receive the first high level, and a second electrode of which is connected to the pull-down node; and a second pull-down node control transistor, a gate electrode of which is connected to the pull-up node, a first electrode of which is connected to the pull-down node, and a second electrode of which is configured to receive the first low level.

To be specific, the pull-up node control module includes a first transistor, a second transistor, a pull-up node control transistor and a storage capacitor. A gate electrode of the pull-up node control transistor is connected to the pull-down node, a first electrode thereof is connected to the pull-up node, and a second electrode thereof is configured to receive the first low level. The storage capacitor is connected between the pull-up node and the gate driving signal output end. During forward scanning, a gate electrode of the first transistor is connected to the reset end, a first electrode is configured to receive the second low level, and a second electrode thereof is connected to the pull-up node; and a gate electrode of the second transistor is connected to the input end, a first electrode thereof is connected to the pull-up node, and a second electrode thereof is configured to receive the second high level. During backward scanning, the gate electrode of the first transistor is connected to the input end, the first electrode thereof is configured to receive the second high level, and the second electrode thereof is connected to the pull-up node; and the gate electrode of the second transistor is connected to the reset end, the first electrode thereof is connected to the pull-up node, and the second electrode thereof is configured to receive the second low level.

To be specific, the pull-up transistor, the pull-down transistor, the pull-up node control transistor, the first pull-down node control transistor and the second pull-down node control transistor are all n-type transistors.

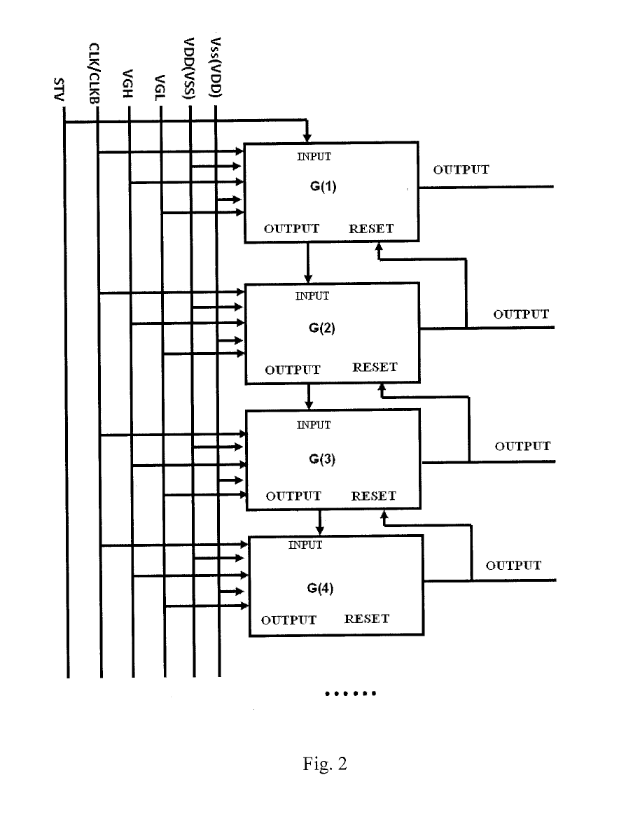

As shown in FIG. 2, the present disclosure provides in one embodiment a shift register including multiple levels of the above-mentioned shift register units arranged on an array substrate. An input end of a first-level shift register unit G(1) is configured to receive a startup signal STV. Apart from the first-level shift register unit, an input end INPUT of a current-level shift register unit is connected to a gate driving signal output end OUTPUT of a previous-level shift register unit; and apart from a last-level shift register unit, a reset end RESET of a current-level shift register unit is connected to a gate driving signal output end OUTPUT of a next-level shift register unit. A reset end RESET of the last-level shift register unit is configured to receive a reset signal (not shown).

In FIG. 2, G(2) represents a second-level shift register unit, G(3) represents a third-level shift register unit, and G(4) represents a fourth-level shift register unit.

Clock signals received by clock signal ends of two adjacent levels of the shift register units are of phases reverse to each other. In FIG. 2, CLK represents a first clock signal, CLKB represents a second clock signal, and CLK is of a phase reverse to CLKB.

The shift register unit will be described hereinafter in conjunction with the embodiments.

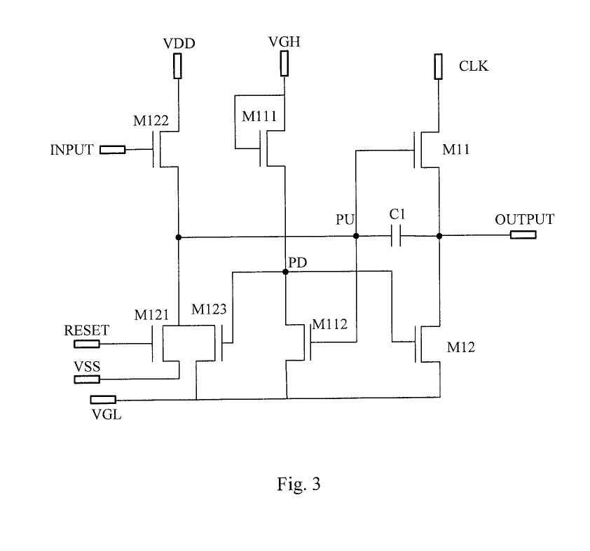

As shown in FIG. 3, an n^{th}-level shift register unit G(n) for forward scanning includes the gate driving signal output end OUTPUT, the input end INPUT, the reset end RESET, the pull-up transistor M11, the pull-down transistor M12, the pull-down node control module 11 and the pull-up node control module 12. A gate electrode of the pull-up transistor M11 is connected to the pull-up node PU, a first electrode thereof is configured to receive the first clock signal CLK, and a second electrode thereof is connected to the gate driving signal output end OUTPUT. A gate electrode of the pull-down transistor M12 is connected to the pull-down node PD, a first electrode thereof is connected to the gate driving signal output end OUTPUT, and a second electrode thereof is configured to receive the first low level VGL.

The pull-down node control module 11 includes: a first pull-down node control transistor M111, a gate electrode of which is configured to receive the first high level VGH, a first electrode of which is configured to receive the first high level VGH, and a second electrode of which is connected to the pull-down node PD; and a second pull-down node control transistor M112, a gate electrode of which is connected to the pull-up node PU, a first electrode of which is connected to the pull-down node PD, and a second electrode of which is configured to receive the first low level VGL.

The pull-up node control module 12 includes: a first transistor M121, a gate electrode of which is connected to the reset end RESET, a first electrode of which is configure to receive the second low level VSS, and a second electrode of which is connected to the pull-up node PU; a second transistor M122, a gate electrode of which is connected to the input end INPUT, a first electrode of which is connected to the pull-up node PU, and a second electrode of which is configured to receive the second high level VDD; a pull-up node control transistor M123, a gate electrode of which is connected to the pull-down node PD, a first electrode of which is connected to the pull-up node PU, and a second electrode of which is configured to receive the first low level VGL; and a storage capacitor C1 connected between the pull-up node PU and the gate driving signal output end OUTPUT.

A clock signal received by the clock signal end of an (n+1)^{th}-level shift register unit G(n+1) is the second clock signal CLKB which is of a phase reverse to CLK.

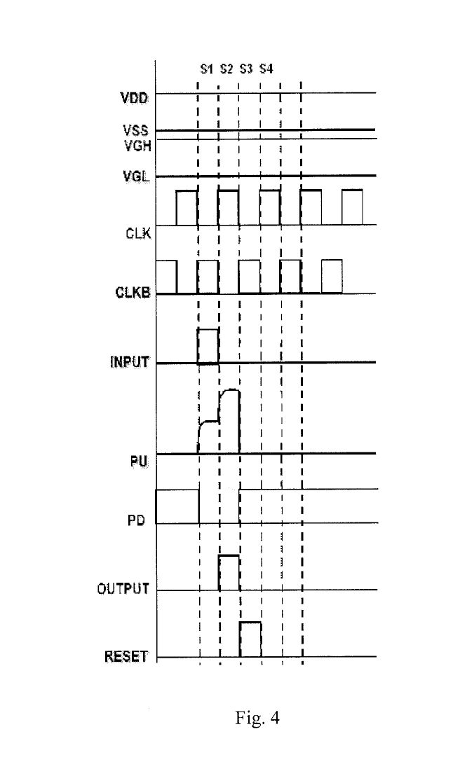

As shown in FIG. 4, when the shift register unit in FIG. 3 performs the forward scanning, an operational procedure within one display period will be described as follows.

At an input stage S1, the input end INPUT is configured to receive a high level signal so as to turn on the second transistor M122. C1 is charged through the high level signal from the input end INPUT so as to pull up the potential of the pull-up node PU and turn on the pull-up transistor M11. At this time, OUTPUT outputs CLK, and CLK is at a low level, i.e., OUTPUT outputs a low level. The pull-up node PU is at a high potential so as to turn on M112, so at this time the pull-down node PD is at a low level, so as to turn off M12 and M123, thereby to output a gate driving signal in a stable manner.

At an output stage S2, the input end INPUT is configured to receive a low level signal so as to turn off the second transistor M122. The pull-up node PU continues to be maintained at a high potential, and the pull-up transistor M11 is maintained in an on state. At this time, CLK is at a high level, the potential of the pull-up node PU is bootstrapped due to a bootstrapping effect, and finally the gate driving signal is transmitted to OUTPUT. OUTPUT outputs CLK and CLK is at a high level, i.e., OUTPUT outputs a high level. At this time, PU is at a high potential, M112 is still in the on state, and PD is discharged, so as to maintain M12 and M123 in the off state, thereby to output the gate driving signal in a stable manner.

At a reset stage S3, the reset end is configured to receive a high level so as to turn on the first transistor M121 and pull down the potential of the pull-up node PU to VSS, thereby to turn off M11 and M112. Because M112 is in the off state, the pull-down node PD is pulled up to the second high level VGH, so as to turn on the pull-down transistor M12 and enable OUTPUT to output the first low level VGL.

At a maintenance stage S4, INPUT and RESET are both configured to receive a low level, so M121 and M122 are turned off. Because PU is discharged at the previous stage by M122, M112 is in the off state and PD is not discharged. At this time, M111 is turned on so as to charge PD, and the potential of PD is pulled up so as to turn on M12 and M123. Noise reduction is performed on PU and OUTPUT, so as to eliminate a coupling noise voltage generated by CLK, thereby to ensure low-voltage output and to output the gate driving signal in a stable manner. In addition, there is no circuit for charging PU, so PU is maintained at a low potential. Further, M111 is maintained in the on state at S4, so PD is maintained at a high level. At this time, M12 and M123 are maintained in the on state at S4, and OUTPUT outputs the first low level VGL. The maintenance stage is always kept until an input stage of a next display period begins.

When the clock signal end of the n^{th}-level shift register unit G(n) is configured to receive the first clock signal CLK, the clock signal end of the (n+1)^{th}-level shift register unit G(n+1) is configured to receive the second clock signal CLKB which is of a phase reverse to CLK (n is a positive integer).

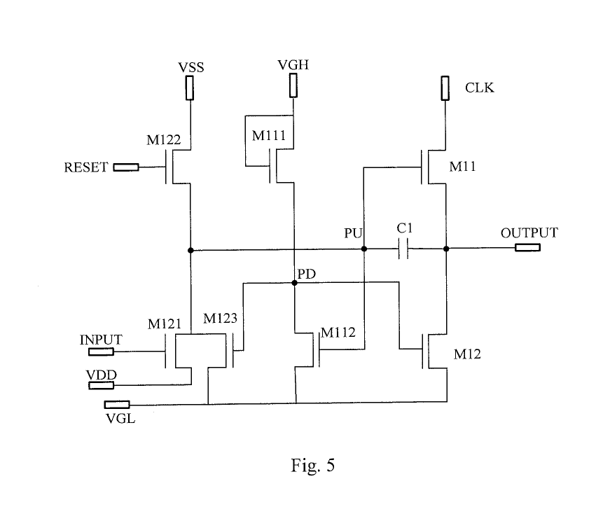

As shown in FIG. 5, the n^{th}-level shift register unit G(n) for backward scanning includes the gate driving signal output end OUTPUT, the input end INPUT, the reset end RESET, the pull-up transistor M11, the pull-down transistor M12, the pull-down node control module 11 and the pull-up node control module 12. A gate electrode of the pull-up transistor M11 is connected to the pull-up node PU, a first electrode thereof is configured to receive the first clock signal CLK, and a second electrode thereof is connected to the gate driving signal output end OUTPUT. A gate electrode of the pull-down transistor M12 is connected to the pull-down node PD, a first electrode thereof is connected to the gate driving signal output end OUTPUT, and a second electrode thereof is configured to receive the first low level VGL.

The pull-down node control module 11 includes: a first pull-down node control transistor M111, a gate electrode of which is configured to receive the first high level VGH, a first electrode of which is configured to receive the first high level VGH, and a second electrode of which is connected to the pull-down node PD; and a second pull-down node control transistor M112, a gate electrode of which is connected to the pull-up node PU, a first electrode of which is connected to the pull-down node PD, and a second electrode of which is configured to receive the first low level VGL.

The pull-up node control module 12 includes: a first transistor M121, a gate electrode of which is connected to the input end INPUT, a first electrode of which is configure to receive the second high level VDD, and a second electrode of which is connected to the pull-up node PU; a second transistor M122, a gate electrode of which is connected to the reset end RESET, a first electrode of which is connected to the pull-up node PU, and a second electrode of which is configured to receive the second low level VSS; a pull-up node control transistor M123, a gate electrode of which is connected to the pull-down node PD, a first electrode of which is connected to the pull-up node PU, and a second electrode of which is configured to receive the first low level VGL; and a storage capacitor C1 connected between the pull-up node PU and the gate driving signal output end OUTPUT.

A clock signal received by the clock signal end of an (n+1)^{th}-level shift register unit G(n+1) is the second clock signal CLKB which is of a phase reverse to CLK.

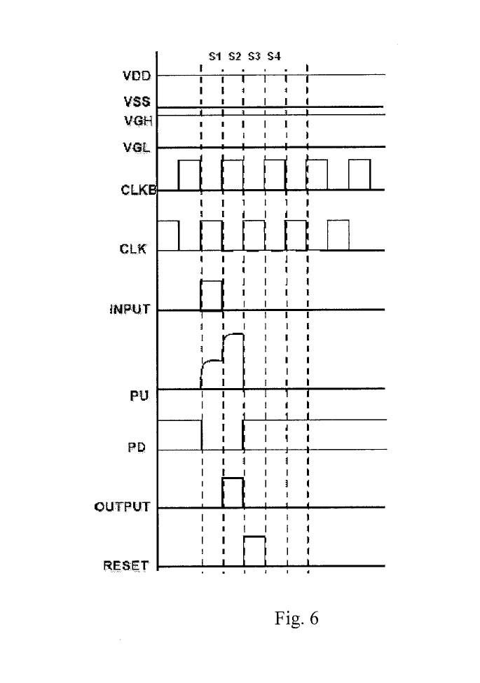

As shown in FIG. 6, when the shift register unit in FIG. 5 performs the backward scanning, an operational procedure within one display period will be described as follows.

At the input stage S1, the input end INPUT is configured to receive a high level signal so as to turn on the first transistor M121. C1 is charged through the high level signal from the input end INPUT so as to pull up the potential of the pull-up node PU and turn on the pull-up transistor M11. At this time, OUTPUT outputs CLK, and CLK is at a low level, i.e., OUTPUT outputs a low level. The pull-up node PU is at a high potential so as to turn on M112, so at this time the pull-down node PD is at a low level, so as to turn off M12 and M123, thereby to output the gate driving signal in a stable manner.

At the output stage S2, the input end INPUT is configured to receive a low level signal so as to turn off the first transistor M121. The pull-up node PU continues to be maintained at a high potential, and the pull-up transistor M11 is maintained in the on state. At this time, CLK is at a high level, the potential of the pull-up node PU is bootstrapped due to a bootstrapping effect, and finally the gate driving signal is transmitted to OUTPUT. OUTPUT outputs CLK and CLK is at a high level, i.e., OUTPUT outputs a high level. At this time, PU is at a high potential, M112 is still in the on state, and PD is discharged, so as to maintain M12 and M123 in the off state, thereby to output the gate driving signal in a stable manner.

At the reset stage S3, the reset end is configured to receive a high level so as to turn on the second transistor M122 and pull down the potential of the pull-up node PU to VSS, thereby to turn off M11 and M112. Because M112 is in the off state, the pull-down node PD is pulled up to the second high level VGH, so as to turn on the pull-down transistor M12 and enable OUTPUT to output the first low level VGL.

At the maintenance stage S4, INPUT and RESET are both configured to receive a low level, so M121 and M122 are turned off. Because PU is discharged at the previous stage by M122, M112 is in the off state and PD is not discharged. At this time, M111 is turned on so as to charge PD, and the potential of PD is pulled up so as to turn on M12 and M123. Noise reduction is performed on PU and OUTPUT, so as to eliminate a coupling noise voltage generated by CLK, thereby to ensure low-voltage output and to output the gate driving signal in a stable manner. In addition, there is no circuit for charging PU, so PU is maintained at a low potential. Further, M111 is maintained in the on state at S4, so PD is maintained at a high level. At this time, M12 and M123 are maintained in the on state at S4, and OUTPUT outputs the first low level VGL. The maintenance stage is always kept until an input stage of a next display period begins.

When the clock signal end of the n^{th}-level shift register unit G(n) is configured to receive the first clock signal CLK, the clock signal end of the (n+1)^{th}-level shift register unit G(n+1) is configured to receive the second clock signal CLKB which is of a phase reverse to CLK (n is a positive integer).

According to the shift register unit in FIG. 3 and the sequence diagram in FIG. 4, it is able for the shift register including multiple levels of shift register units to achieve both the forward scanning and the backward scanning merely by one circuit structure, i.e., it is merely required to correspondingly change a signal received by the first electrode of the first transistor and a signal received by the second electrode of the second transistor when scanning directions are switched (i.e., when the input signal and the reset signal are exchanged with each other). As a result, it is able to reduce the number of the desired transistors, thereby to reduce the resultant power consumption.

The present disclosure further provides in one embodiment a method for driving the above-mentioned shift register unit which includes, during the forward scanning and the backward scanning within each display period, steps of:

at the input stage, enabling the input end to receive a high level, enabling the reset end to receive a low level, enabling the clock signal end to receive a low level, controlling by the a pull-up node control module the pull-up node to be pulled up to a high potential so as to control the pull-up transistor to be in the on state, and controlling by the pull-down node control module the pull-down node to be pulled down to a low level so as to control the pull-down transistor to be in the off state, thereby enabling the gate driving signal output end to output a low level;

at the output stage, enabling the input end to receive a low level, enabling the reset end to receive a low level, enabling the clock signal end to receive a high level, controlling by the pull-up node control module the potential of the pull-up node to be bootstrapped so as to control the pull-up transistor to be maintained in the on state, and controlling by the pull-down node control module the pull-down node to be maintained at a low level so as to control the pull-down transistor to be maintained in the off state, thereby enabling the gate driving signal output end to output a high level;

at the reset stage, enabling the input end to receive a low level, enabling the reset end to receive a high level, controlling by the pull-up node control module the potential of the pull-up node to be pulled down so as to control the pull-up transistor to be in the off state, and controlling by the pull-down node control module the pull-down node to be pulled up to a high level so as to control the pull-down transistor to be in the on state, thereby enabling the gate driving signal output end to output a low level; and

at the maintenance stage, controlling by the pull-up node control module the pull-up node to be maintained at a low level so as to control the pull-up transistor to be in the off state, and controlling by the pull-down node control module the potential of the pull-down node to be pulled up continuously so as to control the pull-down transistor to be in the on state, thereby enabling the gate driving signal output end to output a low level continuously.

The present disclosure further provides in one embodiment a display device including the above-mentioned shift register. The display device may be a liquid crystal display, a liquid crystal TV, an organic light-emitting diode (OLED) display panel, an OLED display, an OLED TV, or an electronic paper.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

What is claimed is:

1. A shift register unit, comprising a gate driving signal output end, an input end, a reset end, a clock signal end, a pull-up transistor, a pull-down transistor, a pull-down node control module and a pull-up node control module, wherein
a gate electrode of the pull-up transistor is connected to a pull-up node, a first electrode thereof is connected to the clock signal end, and a second electrode thereof is connected to the gate driving signal output end;
a gate electrode of the pull-down transistor is connected to a pull-down node, a first electrode thereof is connected to the gate driving signal output end, and a second electrode thereof is configured to receive a first low level;
the pull-down node control module is configured to receive the first low level and a first high level, connected to the pull-up node and the pull-down node, and configured to control the pull-down node to be at a low potential at an input stage of each display period and control the pull-down node to be maintained at a low potential at an output stage of each display period so as to control the pull-down transistor to be in an off state, and to control the pull-down node to be pulled up to a high level at a reset stage of each display period and control the potential of the pull-down node to be pulled up continuously at a maintenance stage of each display period so as to control the pull-down transistor to be in an on state, thereby to enable the gate driving signal output end to output a low level; and
the pull-up node control module is configured to receive the first low level, a second low level and a second high level, connected to the pull-up node, the pull-down node, the input end and the reset end, and configured to control the pull-up node to be pulled up to a high potential at the input stage of each display period and control the potential of the pull-up node to be bootstrapped at the output stage of each display period so as to control the pull-up transistor to be maintained in an on state and enable the gate driving signal output end to output a clock signal from the clock signal end, and to control the pull-up node to be pulled down to a low level at the reset stage of each display period and control the pull-up node to be maintained at a low level at the maintenance stage of each display period so as to control the pull-up transistor to be in an off state.

2. The shift register unit according to claim 1, wherein the pull-down node control module comprises:
a first pull-down node control transistor, a gate electrode of which is configured to receive the first high level, a first electrode of which is configured to receive the first high level, and a second electrode of which is connected to the pull-down node; and
a second pull-down node control transistor, a gate electrode of which is connected to the pull-up node, a first electrode of which is connected to the pull-down node, and a second electrode of which is configured to receive the first low level.

3. The shift register unit according to claim 1, wherein the pull-up node control module comprises a first transistor, a second transistor, a pull-up node control transistor and a storage capacitor;
a gate electrode of the pull-up node control transistor is connected to the pull-down node, a first electrode thereof is connected to the pull-up node, and a second electrode thereof is configured to receive the first low level;
the storage capacitor is connected between the pull-up node and the gate driving signal output end;
during forward scanning, a gate electrode of the first transistor is connected to the reset end, a first electrode is configured to receive the second low level, and a second electrode thereof is connected to the pull-up node; and a gate electrode of the second transistor is connected to the input end, a first electrode thereof is connected to the pull-up node, and a second electrode thereof is configured to receive the second high level; and
during backward scanning, the gate electrode of the first transistor is connected to the input end, the first electrode thereof is configured to receive the second high level, and the second electrode thereof is connected to the pull-up node;
and the gate electrode of the second transistor is connected to the reset end, the first electrode thereof is connected to the pull-up node, and the second electrode thereof is configured to receive the second low level.

4. The shift register unit according to claim 2, wherein the pull-up transistor, the pull-down transistor, the pull-up node control transistor, the first pull-down node control transistor and the second pull-down node control transistor are all n-type transistors.

5. The shift register unit according to claim 3, wherein the pull-up transistor, the pull-down transistor, the pull-up node control transistor, the first pull-down node control transistor and the second pull-down node control transistor are all n-type transistors.

6. A method for driving the shift register unit according to claim 1, comprising, during forward scanning and backward scanning within each display period, steps of:
at an input stage, enabling an input end to receive a high level, enabling a reset end to receive a low level, enabling a clock signal end to receive a low level, controlling by a pull-up node control module a pull-up node to be pulled up to a high potential so as to control a pull-up transistor to be in an on state, and controlling by a pull-down node control module a pull-down node to be pulled down to a low level so as to control a pull-down transistor to be in an off state, thereby enabling a gate driving signal output end to output a low level;
at an output stage, enabling the input end to receive a low level, enabling the reset end to receive a low level, enabling the clock signal end to receive a high level, controlling by the pull-up node control module the potential of the pull-up node to be bootstrapped so as to control the pull-up transistor to be maintained in the on state, and controlling by the pull-down node control module the pull-down node to be maintained at a low level so as to control the pull-down transistor to be maintained in the off state, thereby enabling the gate driving signal output end to output a high level;
at a reset stage, enabling the input end to input a low level, enabling the reset end to receive a high level, controlling by the pull-up node control module the potential of the pull-up node to be pulled down so as to control the pull-up transistor to be in an off state, and controlling by the pull-down node control module the pull-down node to be pulled up to a high level so as to control the pull-down transistor to be in an on state, thereby enabling the gate driving signal output end to output a low level; and
at a maintenance stage, controlling by the pull-up node control module the pull-up node to be maintained at a low level so as to control the pull-up transistor to be in the off state, and controlling by the pull-down node control module the potential of the pull-down node to be pulled up continuously so as to control the pull-down transistor to be in the on state, thereby enabling the gate driving signal output end to output a low level continuously.

7. A shift register, comprising multiple levels of the shift register units according to claim 1 arranged on an array substrate, wherein
an input end of a first-level shift register unit is configured to receive a startup signal;
apart from the first-level shift register unit, an input end of a current-level shift register unit is connected to a gate driving signal output end of a previous-level shift register unit;
apart from a last-level shift register unit, a reset end of a current-level shift register unit is connected to a gate driving signal output end of a next-level shift register unit;
a reset end of the last-level shift register unit is configured to receive a reset signal; and
clock signals received by clock signal ends of two adjacent levels of the shift register units are of phases reverse to each other.

8. The shift register according to claim 7, wherein the pull-down node control module comprises:
a first pull-down node control transistor, a gate electrode of which is configured to receive the first high level, a first electrode of which is configured to receive the first high level, and a second electrode of which is connected to the pull-down node; and
a second pull-down node control transistor, a gate electrode of which is connected to the pull-up node, a first electrode of which is connected to the pull-down node, and a second electrode of which is configured to receive the first low level.

9. The shift register according to claim 7, wherein the pull-up node control module comprises a first transistor, a second transistor, a pull-up node control transistor and a storage capacitor;
a gate electrode of the pull-up node control transistor is connected to the pull-down node, a first electrode thereof is connected to the pull-up node, and a second electrode thereof is configured to receive the first low level;
the storage capacitor is connected between the pull-up node and the gate driving signal output end;
during forward scanning, a gate electrode of the first transistor is connected to the reset end, a first electrode is configured to receive the second low level, and a second electrode thereof is connected to the pull-up node; and a gate electrode of the second transistor is connected to the input end, a first electrode thereof is connected to the pull-up node, and a second electrode thereof is configured to receive the second high level; and
during backward scanning, the gate electrode of the first transistor is connected to the input end, the first electrode thereof is configured to receive the second high level, and the second electrode thereof is connected to the pull-up node; and the gate electrode of the second transistor is connected to the reset end, the first electrode thereof is connected to the pull-up node, and the second electrode thereof is configured to receive the second low level.

10. The shift register according to claim 8, wherein the pull-up transistor, the pull-down transistor, the pull-up node control transistor, the first pull-down node control transistor and the second pull-down node control transistor are all n-type transistors.

11. The shift register according to claim 9, wherein the pull-up transistor, the pull-down transistor, the pull-up node control transistor, the first pull-down node control transistor and the second pull-down node control transistor are all n-type transistors.

12. A display device, comprising the shift register according to claim 7.

13. The display device according to claim 12, wherein the pull-down node control module comprises:
a first pull-down node control transistor, a gate electrode of which is configured to receive the first high level, a first electrode of which is configured to receive the first high level, and a second electrode of which is connected to the pull-down node; and
a second pull-down node control transistor, a gate electrode of which is connected to the pull-up node, a first electrode of which is connected to the pull-down node, and a second electrode of which is configured to receive the first low level.

14. The display device according to claim 12, wherein the pull-up node control module comprises a first transistor, a second transistor, a pull-up node control transistor and a storage capacitor;
a gate electrode of the pull-up node control transistor is connected to the pull-down node, a first electrode thereof is connected to the pull-up node, and a second electrode thereof is configured to receive the first low level;
the storage capacitor is connected between the pull-up node and the gate driving signal output end;
during forward scanning, a gate electrode of the first transistor is connected to the reset end, a first electrode is configured to receive the second low level, and a second electrode thereof is connected to the pull-up node; and a gate electrode of the second transistor is connected to the input end, a first electrode thereof is connected to the pull-up node, and a second electrode thereof is configured to receive the second high level; and
during backward scanning, the gate electrode of the first transistor is connected to the input end, the first electrode thereof is configured to receive the second high level, and the second electrode thereof is connected to the pull-up node; and the gate electrode of the second transistor is connected to the reset end, the first electrode thereof is connected to the pull-up node, and the second electrode thereof is configured to receive the second low level.

15. The display device according to claim 13, wherein the pull-up transistor, the pull-down transistor, the pull-up node control transistor, the first pull-down node control transistor and the second pull-down node control transistor are all n-type transistors.

16. The display device according to claim 14, wherein the pull-up transistor, the pull-down transistor, the pull-up node control transistor, the first pull-down node control transistor and the second pull-down node control transistor are all n-type transistors.
